(19) United States
(12) Patent Application Publication
(10) Pub. No.: US 2006/0108233 A1
(43) Pub. Date: May 25, 2006

(54) Method of manufacturing form factor disk

(76) Inventors: Yong Goo Yoo, Yuseong-gu (KR); Woo Seok Cheong, Yuseong-gu (KR); Ho Jun Ryu, Seoul (KR); Sung Q. Lee, Yuseong-gu (KR); Mun Cheol Paek, Yuseong-gu (KR); Eun Kyoung Kim, Yuseong-gu (KR)

Correspondence Address: LADAS & PARRY LLP, 224 SOUTH MICHIGAN AVENUE, SUITE 1600, CHICAGO, IL, 60604, US

(21) Appl. No.: 11/148,689

(22) Filed: Jun. 9, 2005

(30) Foreign Application Priority Data
Nov. 25, 2004 (KR) 2004-97653

(51) Int. Cl. B05D 5/12; C25D 5/56; C23C 14/00; C25D 3/56

(52) U.S. Cl. 205/255; 427/127; 204/192.2; 205/164

(57) ABSTRACT

Provided is a method of manufacturing a form factor disk such as an optical or magnetic disk for use in electronic appliances and information appliances. The method includes forming a hub for readily mounting the disk to a magnetic rotational disk connected to a spindle motor of the information appliances by depositing or plating a magnetic material, whereby it is possible to minimize a thickness of the disk, simplifying a manufacturing process, allowing an ultra-small and ultra-slim form factor disk to be manufactured, and therefore, facilitating ultra-minimization and ultra-slim of the information appliances.

### CROSS-REFERENCE TO RELATED APPLICATION

This application claims priority to and the benefit of Korean Patent Application No. 2004-97653, filed Nov. 25, 2004, the disclosure of which is incorporated herein by reference in its entirety.

### BACKGROUND

1. Field of the Invention

The present invention relates to a method of manufacturing a form factor disk such as an optical or magnetic disk for use in electronic appliances, information appliances and so forth, and more particularly, to a method of manufacturing a form factor disk capable of minimizing a thickness of the disk and simplifying a manufacture process.

2. Discussion of Related Art

As information technology advances, performance of electronic appliances or information appliances has been rapidly improved. Also, as personal information storage capacity increases, demand of a form factor disk has been continuously increased.

Typical information appliances such as an optical recording and reproducing apparatus have been rapidly minimized and slimmed down in order to increase mobility of information and to be mounted in a small computer or a mobile phone. As a result, minimization of an information storage medium as a detachable disk also has been rapidly performed. In order to minimize the form factor disk, a sectional area and a thickness of the form factor disk should be more reduced.

In general, the form factor disk such as an optical or magnetic disk includes a circular disk 1 made of a polycarbonate material and having a hole at its center as shown in FIG. 1, and upper and lower metal hubs 3 located at upper and lower parts of the circular disk and having a hole 4 aligned with the hole 2 as shown FIG. 2.

The metal hubs 3 are attached to a magnetic rotational disk (a magnetic chuck) connected to a rotational shaft of a spindle motor with a rotational shaft of the information appliances being inserted through the holes 2 and 4. Information is stored in an information storage region 5 of the disk 1 or the information stored in the information storage region 5 is read with the disk 1 being rapidly rotated about the rotational shaft depending on rotation of the magnetic rotational disk. At this time, the metal hubs 3 are fixed by magnetic attraction of the magnetic rotational disk to be not deviated from the center axis or to be not shaken even though it is rotated at a high speed. Therefore, the magnetic rotational disk should have the magnetic attraction such that the disk does not slide from the rotational shaft.

Conventionally, as shown in FIG. 3, a connecting layer 6 made of a polymer material functioning as a shock absorber is attached to the upper and lower metal hubs 3a and 3b using adhesive agent such as epoxy. The upper and lower metal hubs 3a and 3b, to which the connecting layer 6 was attached, are located at the upper and lower parts of the disk 1 and attached such that the holes 4 of the upper and lower metal hubs 3a and 3b is aligned with the hole 2 of the disk 1. Then, a groove is formed at a periphery of the connecting layer 6, and the periphery is bended, thereby fixing them using mechanical force.

However, the following problems may be encountered when the disk is manufactured by the method.

First, since the connecting layer 6 and the metal hubs 3 are layered on the upper and lower parts of the disk 1, the center thickness of the disk becomes larger. When the thickness of the disk becomes larger, since a height of the rotational shaft of the information appliances should be also increased to rotate the disk, the information appliance becomes thicker. As a result, it is difficult to make the appliances ultra-small and ultra-slim.

Second, since the metal hubs 3 are attached to the disk 1 through various processes, the processes are complicated. That is, since the upper and lower metal hubs 3a and 3b are respectively attached to the upper and lower part of the disk 1 after attaching the upper and lower metal hubs 3a and 3b to the connecting layer 6, the number of manufacturing processes is increased, thereby increasing the manufacture cost.

Third, when the upper and lower metal hubs 3a and 3b are attached to the upper and lower parts of the disk, respectively, since the upper and lower metal hubs 3a and 3b should be aligned and attached in a horizontal state, location alignment is difficult, thereby decreasing productivity.

### SUMMARY OF THE INVENTION

The present invention, therefore, solves aforementioned problems associated with conventional methods by providing a method of manufacturing a form factor disk capable of minimizing a thickness of the disk and simplifying manufacturing processes.

In an exemplary embodiment of the present invention, a method of manufacturing a form factor disk includes: providing a circular disk having an information storage region and a hole formed at a center portion thereof; forming a seed layer at the center portion of the disk; and forming a hub by installing an electrode on the seed layer and plating a magnetic material on the seed layer using an electroplating method.

In another exemplary embodiment of the present invention, a method of manufacturing a form factor disk includes: providing a circular disk having an information storage region and a hole formed at a center portion thereof; and forming a hub by depositing a magnetic material on the center portion of the disk.

### BRIEF DESCRIPTION OF THE DRAWINGS

The above and other features of the present invention will be described in reference to certain exemplary embodiments thereof with reference to the attached drawings in which:

FIG. 1 is a plan view of a conventional form factor disk;

FIG. 2 is a plan view of the metal hub shown in FIG. 1;

FIG. 3 is a cross-sectional view taken along the line A1-A2 of FIG. 1;

FIGS. 4A and 4B are cross-sectional views illustrating a method of manufacturing a form factor disk in accordance with an exemplary embodiment of the present invention;

FIG. 5 is a plan view of FIG. 4A; and

FIG. 6 is a graph representing variations of attraction depending on intensity of leakage magnetic field formed by a magnetic rotational disk made of a permanent magnet.

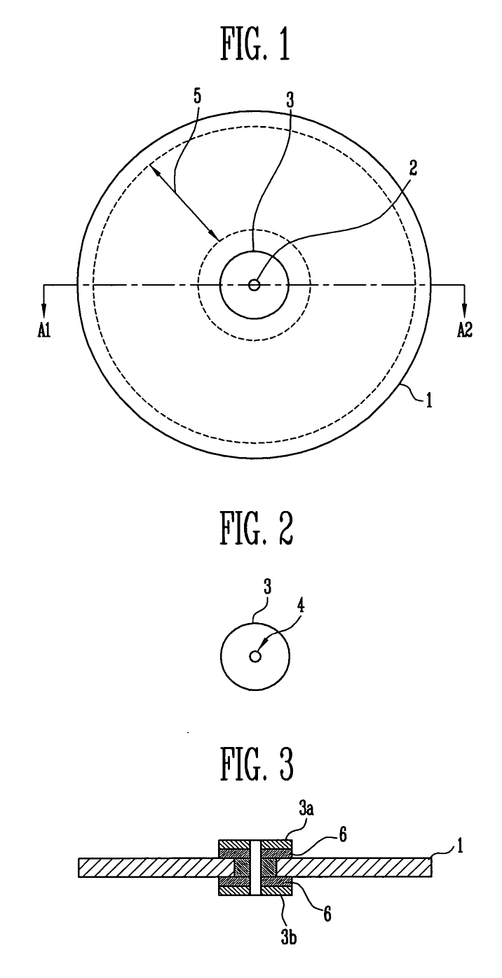

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

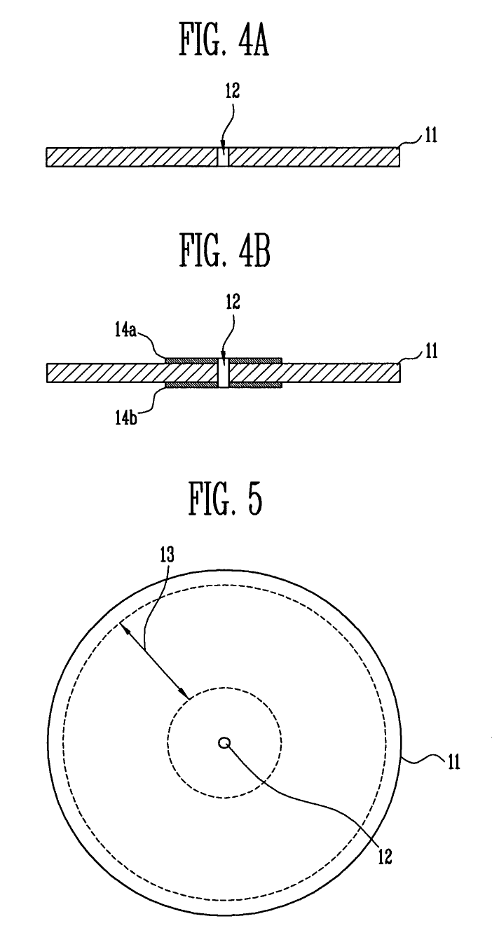

FIGS. 4A and 4B are cross-sectional views illustrating a method of manufacturing a form factor disk in accordance with an exemplary embodiment of the present invention.

Referring to FIG. 4A, as shown in FIG. 5, a circular disk 11 made of a polycarbonate material, and having a hole 12 at its center and an information storage region 13 spaced apart from the hole 12 is manufactured. The disk 11 is manufactured to have a diameter of not more than 50 mm and a thickness of not more than 1 mm, and the hole 12 is formed to have a diameter, for example, of not more than 3 mm such that the rotational shaft can be inserted.

Referring to FIG. 4B, a predetermined size of hubs 14a and 14b are formed by depositing or plating a magnetic material at upper and lower center parts of the disk 11 using an electroplating method or a vacuum deposition method. At this time, the hubs 14a and 14b are formed to have a diameter of not more than 20 mm, for example, a diameter of 10˜20 mm, and may be formed at only one surface of the disk 11.

In the case of using the electroplating method, first, a seed layer (not shown) is formed at a center portion of the disk 11 to a thickness of tens of nm using a vacuum deposition method. The seed layer is formed of a conductive layer such as Ni, Cu and so on. Then, an electrode is installed on the seed layer, and the magnetic material is plated on the seed layer using the electroplating method.

In the case of using the vacuum deposition method such as a sputtering method, an electron beam deposition method, and so forth, since the polycarbonate constituting the disk 11 is sensitive to heat, the disk 11 is cooled during the deposition of the magnetic material. In addition, a mask as a shadow mask is used to allow the magnetic material to be deposited at only the center portion of the disk 11.

The magnetic material may use a high permeability material such as an Fe-based alloy, permalloy (NiFe), FeSi, FeZrN and so on. When these materials are used, it is possible to maximize attraction to the magnetic rotational disk connected to a rotational shaft of the spindle motor.

The hubs 14a and 14b should have a thickness corresponding to the attraction such that the hubs 14a and 14b are not slid or shaken from the magnetic rotational disk made of a permanent magnet when the disk is rotated. Therefore, in order to satisfy this condition, the magnetic attraction between the magnetic rotational disk made of a permanent magnet and the hubs 14a and 14b made of a magnetic material should have an intensity sufficient to endure a weight of the disk.

On the assumption that the hubs 14a and 14b have a diameter of 14 mm, the hole 12 formed at the center portion of the disk has a diameter of 2.8 mm, and the magnetic rotational disk made of a permanent magnet has the same size as the hubs 14a and 14b, when the magnetic material is iron (density=7.86 g/cm³), the hubs 14a and 14b have a thickness of about 50 μm and a weight of about 57 dyne. Therefore, the magnetic attraction corresponding thereto can be obtained using the following formula 1.
F=AB²/8π [Formula 1]

where, A is an area of a contact surface, and B is a magnetic induction value of a permanent magnet.

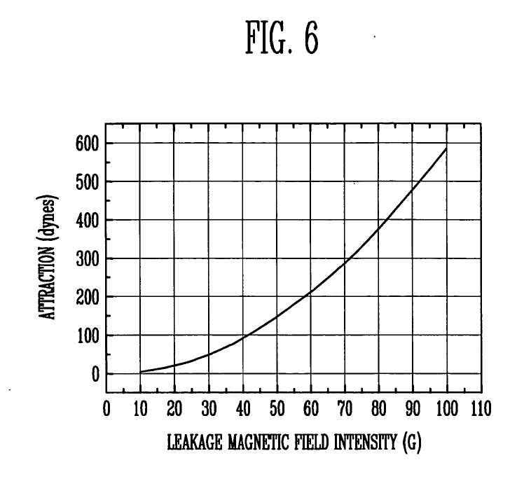

FIG. 6 represents variations of attraction depending on intensity of leakage magnetic field of the permanent magnet calculated using Formula 1.

Viewing from FIG. 6, the leakage magnetic field of the magnetic rotational disk made of a permanent magnet should have an intensity of not less than 35 G. Therefore, the magnetic rotational disk made of a permanent magnet should have appropriate magnetic field intensity since it is difficult to attach and detach the disk smoothly when the magnetic field intensity is too large.

As can be seen from the foregoing, the present invention is capable of minimizing a thickness of the disk and simplifying a manufacturing process by depositing or plating the magnetic material to form the hubs. As a result, it is possible to manufacture an ultra-small and ultra-slim form factor disk, and therefore, to facilitate ultra-minimization and ultra-slim of information appliances.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A method of manufacturing a form factor disk, comprising:
providing a circular disk having an information storage region and a hole formed at a center portion thereof;
forming a seed layer at the center portion of the disk; and
forming a hub by installing an electrode on the seed layer and plating a magnetic material on the seed layer using an electroplating method.

2. The method according to claim 1, wherein the disk is made of a polycarbonate material.

3. The method according to claim 1, wherein the seed layer is formed of one selected from Ni and Cu.

4. The method according to claim 1, wherein the hub is formed to have a diameter of 10˜20 mm.

5. The method according to claim 1, wherein the hubs are formed at both surfaces of the disk.

6. The method according to claim 1, wherein the magnetic material uses one selected from a group consisting of an Fe-based alloy, permalloy (NiFe), FeSi, and FeZrN.

7. A method of manufacturing a form factor disk, comprising:
providing a circular disk having an information storage region and a hole formed at a center portion thereof; and
forming a hub by depositing a magnetic material on the center portion of the disk.

8. The method according to claim 7, wherein depositing the magnetic material is performed using one selected from a sputtering method and an electron beam deposition method.

9. The method according to claim 7, wherein a mask is used in order to deposit the magnetic material on only the center portion of the disk.

10. The method according to claim 7, wherein, while depositing the magnetic material, the disk is cooled.

11. The method according to claim 7, wherein the disk is made of a polycarbonate material.

12. The method according to claim 7, wherein the hub is formed to have a diameter of 10˜20 mm.

13. The method according to claim 7, wherein the hubs are formed at both surfaces of the disk.

14. The method according to claim 7, wherein the magnetic material uses one selected from a group consisting of an Fe-based alloy, permalloy (NiFe), FeSi, and FeZrN.
